(19) United States
(12) Patent Application Publication
(10) Pub. No.: US 2007/0029559 A1
(43) Pub. Date: Feb. 8, 2007

(54) Light emitting chip carrier structure

(75) Inventors: Ming-Shun Lee, Taipei (TW); Ping-Ru Sung, Taipei (TW)

Correspondence Address: TROXELL LAW OFFICE PLLC, SUITE 1404, 5205 LEESBURG PIKE, FALLS CHURCH, VA, 22041, US

(73) Assignee: Taiwan Oasis Technology Co., Ltd.

(21) Appl. No.: 11/196,428

(22) Filed: Aug. 4, 2005

(51) Int. Cl. H01L 33/00

(52) U.S. Cl. 257/98

(57) ABSTRACT

A light emitting chip carrier structure includes a basin with a predetermined height protruded from the surface of a substrate for containing a carrier of a light emitting chip, and a package material for packaging the light emitting chip and the basin, so as to greatly increase the light emitting angle of the light emitting chip, while increasing the contact area of the package material, enhancing the adhesion between the package material and the substrate, and improving the overall brightness performance and reliability of the light emitting diode.

### BACKGROUND OF THE INVENTION

1. Field of the Invention

The present invention relates to a brightness enhancement technology for light emitting diodes, and more specifically to a carrier structure capable of increasing the light emitting angle of a light emitting chip and a method of manufacturing such carrier structure to produce a light emitting diode with a brightness enhancement effect.

2. Description of the Related Art

In general, the basic structure of a light emitting diode includes a related package material for packaging a light emitting chip and a gold wire for connecting the light emitting chip with related circuits, so that the light emitting chip can produce a light source when electrically connected. The light source is emitted from the package material to the outside, or the wavelength of the light source of the light emitting chip is combined with a special effect material (such as a fluorescent material) in the package material to produce the desired color lights.

In addition to the function of packaging the light emitting chip, the package material also has the function of refracting and diffusing lights, so that the light source of the light emitting chip can provide full brightness for almost the whole packaged area. Referring to FIG. 1, a present common light emitting diode structure that directly uses a substrate 10 as a carrier of the light emitting chip 20, and this type of light emitting diode has a recessed base 11 deeply implanted into a surface of the substrate 10 at a predetermined position of the substrate 10. The recessed base 11 is provided for fixing the light emitting chip 20 and serving as a space for filling a package material 30. Therefore, the area of the package material 30 is limited within the recessed base 11, and the light source produced by the light emitting chip 20 is not only blocked by a substrate region around the recessed base 11, but also restricts the range of refraction and diffusion of the light source with respect to the package material 30. As a result, the overall brightness performance of the light emitting diode cannot be enhanced.

### SUMMARY OF THE INVENTION

In view of the foregoing shortcomings of the prior art, the inventor of the present invention based on years of experience in the related field to conduct extensive researches and experiments to overcome the aforementioned shortcomings and finally invented the present invention.

It is a primary objective of the present invention to provide a light emitting diode carrier structure comprising a basin with a predetermined height protruded from a surface of a substrate for containing the carrier of a light emitting chip; a gold wire for coupling the electrodes of the light emitting chip with the circuit of the substrate; and a package material for packaging the light emitting chip, the gold wire and the basin, so as to increase the light emitting angle of the light emitting chip, while increasing the contact area of the package material, enhancing the adhesion between the package material and the substrate, and improving the overall brightness performance and reliability of the light emitting diode.

### BRIEF DESCRIPTION OF THE DRAWINGS

FIG. 1 is a cross-sectional view of a prior art light emitting diode;

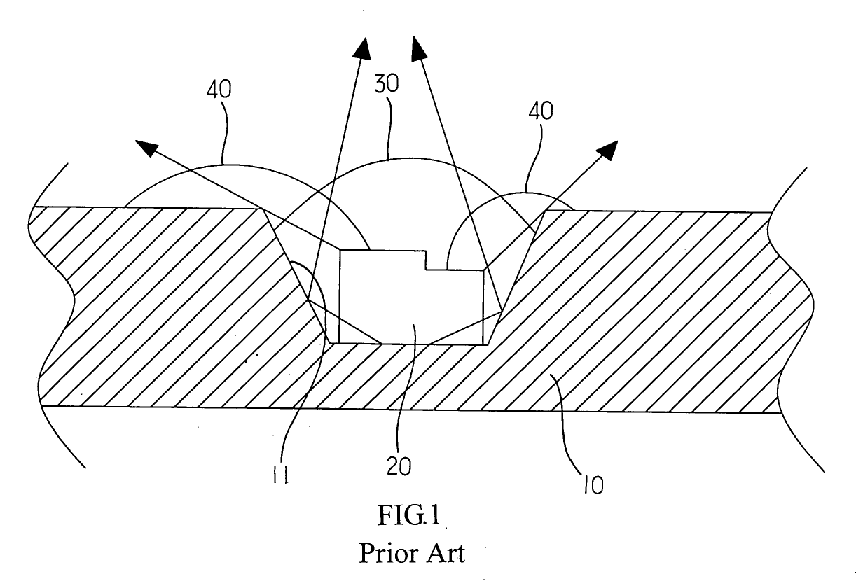

FIG. 2 is a perspective view of a light emitting diode according to a first preferred embodiment of the present invention;

FIG. 3 is an exploded view of a light emitting chip carrier structure of a according to a first preferred embodiment of the present invention;

FIG. 4 is a cross-sectional view of a light emitting diode according to a second preferred embodiment of the present invention;

FIGS. 5A to 5D are flow charts of the manufacturing process of a light emitting diode according to a second preferred embodiment of the present invention; and

FIGS. 6A to 6D are flow charts of anther manufacturing process of a light emitting diode according to a second preferred embodiment of the present invention.

### DETAILED DESCRIPTION OF THE PREFERRED EMBODIMENTS

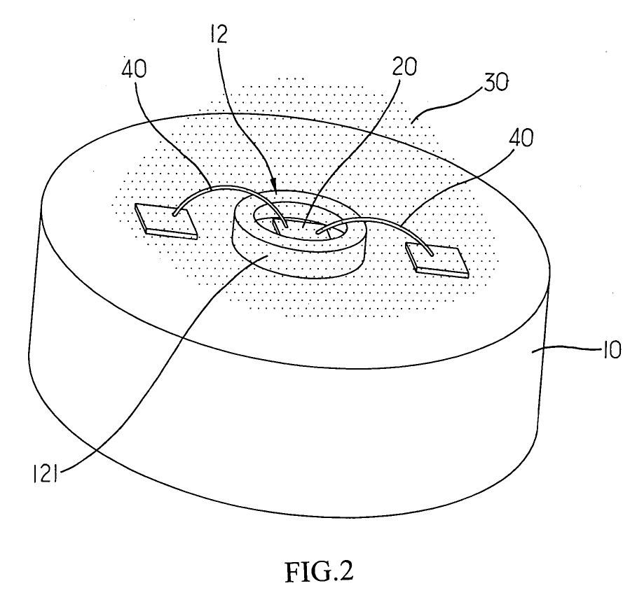

The light emitting chip carrier structure in accordance with the present invention provides a carrier structure capable of increasing the light emitting angle of a light emitting chip and a method of manufacturing such carrier structure to produce a light emitting diode with a brightness enhancement effect. Referring to FIG. 2, the present invention comprises a basin 12 with a predetermined height protruded from a surface of a substrate 10 for containing a light emitting chip 20; a gold wire 40 for coupling the electrodes of the light emitting chip 20 with the circuit of the substrate 10; and a package material 30 for packaging the light emitting chip 20, the gold wire 40 and the basin 12. Under the condition of packaging the light emitting chip 20, the gold wire 40 and the basin 12 by the package material 30, the light emitting chip 20 is not blocked by the substrate 10 as much, and the area of the package material 30 is increased. Therefore, the light emitting angle of the light emitting chip 20 is increased, and the overall brightness performance of the light emitting diode is enhanced.

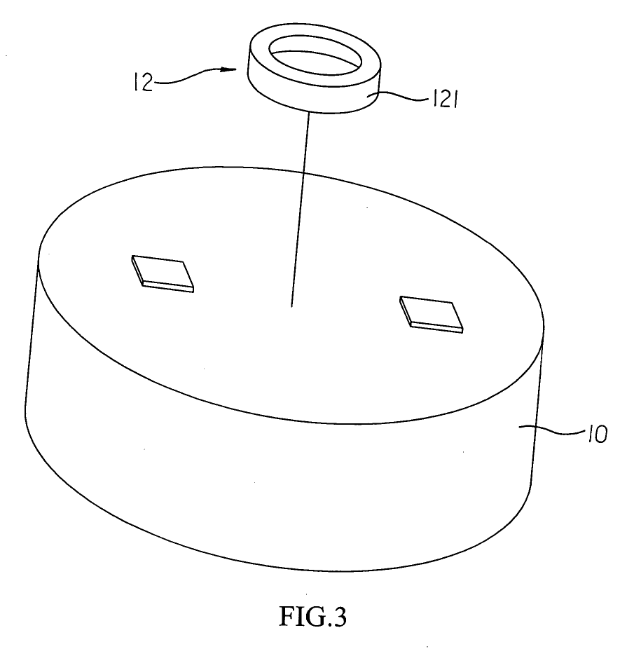

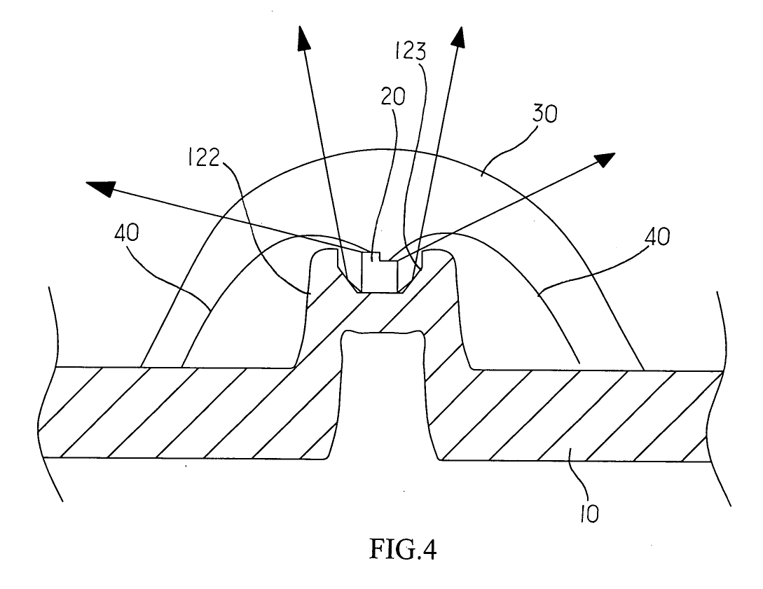

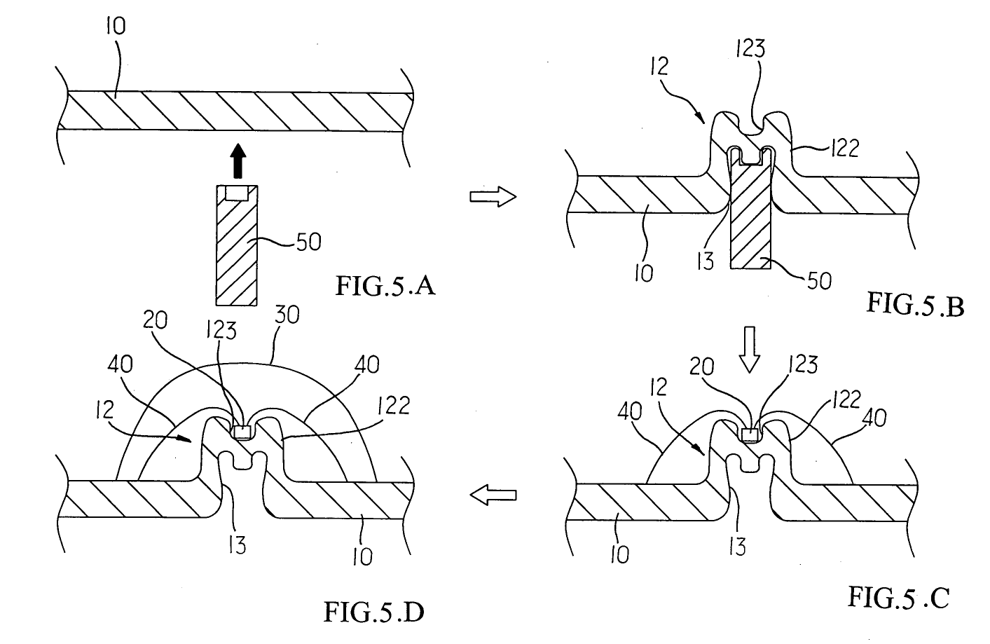

The basin 12 of the preferred embodiment is made of a circular body 121 (or a concave cup) adhered onto a surface of the substrate 10 as shown in FIG. 3 or is a structure integrally formed with the substrate 10 as shown in FIG. 4. In this embodiment, the substrate 10 is an aluminum based copper clad laminate or a copper based copper clad laminate as shown in FIGS. 5A and 5B. The substrate 10 (or a metal laminate) is punched to form at least one protruding member 122 with a predetermined height. In the meantime, the protruding member 122 forms a pit 123 at its top to define a basin 12 for containing the light emitting chip 20. In FIG. 5C, the light emitting chip 20 is disposed in the pit 123 of the basin 12 and coupled with the gold wire 40. In FIG. 5, the light emitting chip 20, the gold wire 40 and the protruding member 122 of the basin 12 are packaged by a package material 30 to constitute a light emitting diode having a brightness enhancement effect.

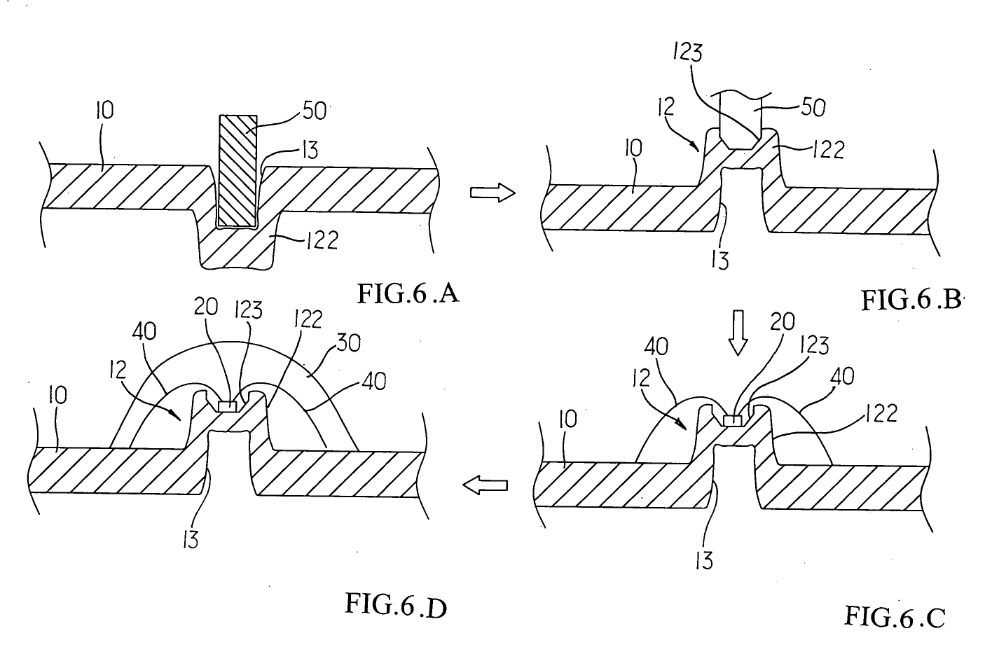

In FIGS. 6A and 6B, the substrate 10 (or a metal laminate) can be punched to form at least one protruding member 122 with a predetermined height and at least a pit 123 disposed on the top of the protruding member 122 to define the basin 12 for containing the light emitting chip 20. In FIG. 6C, the light emitting chip 20 is disposed in the pit 123 of the basin 12 and coupled to the gold wire 40. In FIG. 6C, the light emitting chip 20, the gold wire 40 and the protruding member 122 of the basin 12 are packaged by a package material 30 to constitute a light emitting diode having a brightness enhancement effect.

It is noteworthy that the cross-sectional structure of a mold 50 according to a preferred embodiment as shown in FIGS. 5A, 5B, 6A and 6B is used to form a circular, elliptical or polygonal pit 123 of the basin 12 as well as forming a recession 13 at the bottom of the basin 12, such that the recession 13 can improve the effect of dissipating the heat produced by the light emitting chip 20.

In summation of the above description, the present invention provides a carrier structure capable of increasing the light emitting angle of a light emitting chip and a method of manufacturing such carrier structure to produce a light emitting diode having a brightness enhancement effect, and herein complies with the patent application requirements and is submitted for patent application. However, the description and its accompanied drawings are used for describing preferred embodiments of the present invention, and it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light emitting chip carrier structure, comprising at least a basin with a predetermined height protruded from a surface of a substrate for accommodating a light emitting chip.

2. The light emitting chip carrier structure of claim 1, wherein said substrate includes a recession disposed at the bottom of said substrate.

3. The light emitting chip carrier structure of claim 1, wherein said basin is integrally formed with said substrate.

4. The light emitting chip carrier structure of claim 1, wherein said substrate is an aluminum based copper clad laminate, a copper based copper clad laminate, or a metal laminate.

5. The light emitting chip carrier structure of claim 1, wherein said basin is added externally onto a surface of said substrate.

6. A method for manufacturing a light emitting chip carrier, comprising the steps of simultaneously producing at least one protruding member with a predetermined height protruded from a metal substrate and forming a pit on the top of said protruding member by a punching action.

7. A method for manufacturing a light emitting chip carrier, comprising the steps of producing at least one protruding member with a predetermined height protruded from a metal substrate by a punching action, and then forming a pit on the top of said protruding member by another punching action.

8. A method for manufacturing a light emitting chip carrier, comprising the step of adhering a circular member with a predetermined height onto a surface of a substrate.

9. The method for manufacturing a light emitting chip carrier, comprising the step of adhering a concave cup with a predetermined height onto a surface of a substrate.

10. A light emitting diode, comprising a basin with a predetermined height protruded from a surface of a substrate, a light emitting chip disposed in said basin, a gold wire for coupling the electrodes of said light emitting and the circuit of said substrate, and a package material for packaging said light emitting chip and said basin.

11. The light emitting diode of claim 10, wherein said substrate includes a recession disposed at the bottom of said basin.

12. The light emitting diode of claim 10, wherein said basin is integrally formed with said substrate.

13. The light emitting diode of claim 10, wherein said substrate is an aluminum based copper clad laminate, a copper based copper clad laminate, or a metal laminate.

14. The light emitting diode of claim 10, wherein said basin is added externally onto a surface of said substrate.
